(19) United States
(12) Patent Application Publication
(10) Pub. No.: US 2010/0309629 A1
(43) Pub. Date: Dec. 9, 2010

(54) METHOD FOR MANUFACTURING VENTED BOARD, METAL PLATE FOR FORMING THE VENTED BOARD, AND METHOD FOR MAKING ELECTRONIC DEVICE HAVING THE VENTED BOARD

(75) Inventors: CHUANG-JIAN LI, Shenzhen City (CN); JUN CHEN, Shenzhen City (CN); JUN LIU, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) Co., LTD., ShenZhen City (CN); HON HAI PRECISION INDUSTRY CO., LTD., Tu-Cheng (TW)

(21) Appl. No.: 12/606,200

(22) Filed: Oct. 27, 2009

(30) Foreign Application Priority Data
Jun. 3, 2009 (CN) 200910302886.4

(51) Int. Cl. H05K 7/20; B32B 3/10; G06K 1/00

(52) U.S. Cl. 361/692; 428/596; 234/2

(57) ABSTRACT

A method for manufacturing a vented board includes the steps of providing a metal plate, forming a mesh area in the plate, and punching a recessed portion on the plate to make at least one part of the mesh area extend to form a side wall of the recessed portion with a thickness of the mesh area substantially remaining constant. The mesh area includes a number of hole units. Each hole unit defines a hole and includes a plurality of borders bounding the hole. Every two adjacent hole units share a corresponding one of the plurality of borders. Before punching the recessed portion, a center line of each border is a curve line.

### BACKGROUND

1. Technical Field

The present disclosure relates to a metal board defining meshes therein.

2. Description of Related Art

An electronic device usually includes a metal shell. A depressed portion may be formed on the shell via punch. The punching process is actually a process that a corresponding part of the shell for forming the depressed portion is extended to become thin and so as to enlarge the area of the part, which may cause the part to be ruptured.

### BRIEF DESCRIPTION OF THE DRAWINGS

FIG. 1 is an isometric view of a first embodiment of an electronic device, the electronic device including a vented board.

FIG. 2 is a plan view of a first embodiment of a metal plate for forming the vented board of FIG. 1.

FIG. 3 is an enlarged view of the circled portion III in FIG. 2.

FIG. 4 shows a flowchart of a method for manufacturing the vented board in FIG. 1.

FIG. 5 is a plan view of a second embodiment of a metal plate for forming a second embodiment of a vented board.

FIG. 6 is an enlarged view of the circled portion VI in FIG. 5.

### DETAILED DESCRIPTION

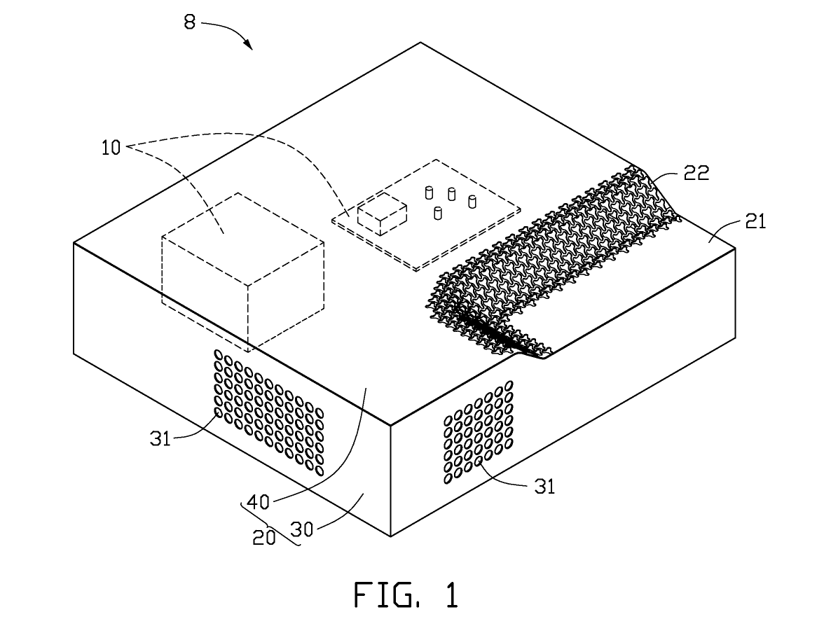

Referring to FIG. 1, a first embodiment of an electronic device 8 includes a metal shell 20, and a plurality of electronic elements 10 mounted in the shell 20.

In the present embodiment, when the plurality of electronic elements 10 work, a maximum frequency of electromagnetic waves generated by the plurality of electronic elements 10 is no more than 2 gigahertz, in other words, a minimum wavelength of the electromagnetic waves generated by the plurality of electronic elements 10 is no less than 150 millimeters (mm).

The shell 20 includes a base 30 for receiving the plurality of electronic elements 10, and a vented board 40 covering on the base 30.

The base 30 may define a plurality of holes 31 therein, for helping dissipating heat. A diameter of each hole 31 is no more than 5 mm, one thirtieth of the minimum wavelength, so as to prevent the electromagnetic waves generated by the plurality of electronic elements 10 from escaping outside the shell 20.

The vented board 40 may be ferric. For example, the vented board 40 may be made from double-cold-rolled plate. The double-cold-rolled plate may be a double-cold-rolled plate (DR-7 plate), which has DR-7 of hardness, 520 newtons per square millimeters (N/mm²) of yield stress, and 11% of percentage of elongation. Alternatively, the double-cold-rolled plate may be a malei plate (DR-9 mL620 plate), which has DR-9 of hardness, 620 N/mm² of yield stress, and 7% of percentage of elongation. The double-cold-rolled plate may also be an ordinary tin plate (DR-9 TH620 plate), which has DR-9 of hardness, 620 N/mm² of yield stress, and 7% of percentage of elongation. In the present embodiment, the DR-9 TH620 plate is selected. Although the percentage of elongation of the DR-9 TH620 plate is less than other kinds of double-cold-rolled plates above mentioned, using the DR-9 TH620 plate can save 5% in material cost comparing to using the DR-9 mL620 plate, and 20% comparing to using the DR-7 plate. In other embodiments, other metal material, such as aluminium alloy or magnesium alloy, may be selected for making the vented board 40.

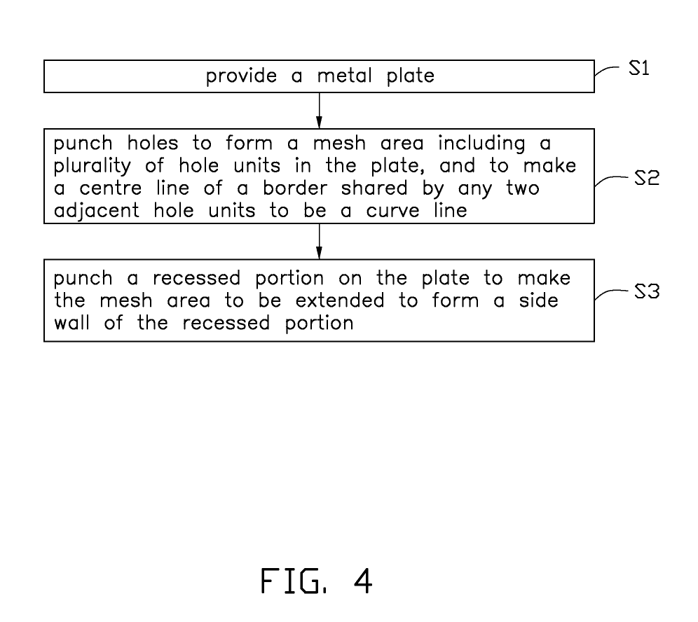

Referring to FIG. 4, a method for manufacturing the vented board 40 includes the following steps.

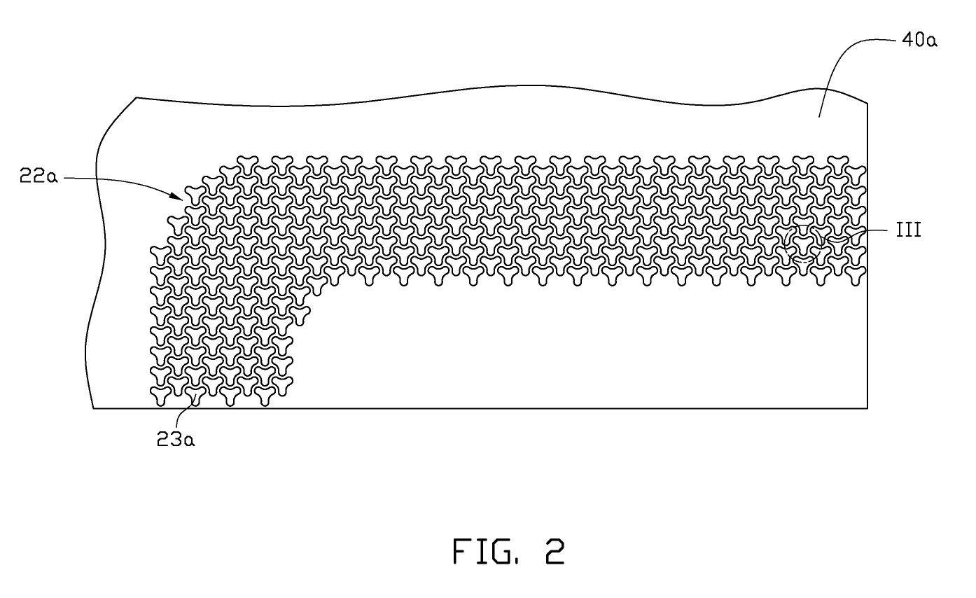

Step S1: provide a flat plate 40a (see FIG. 2).

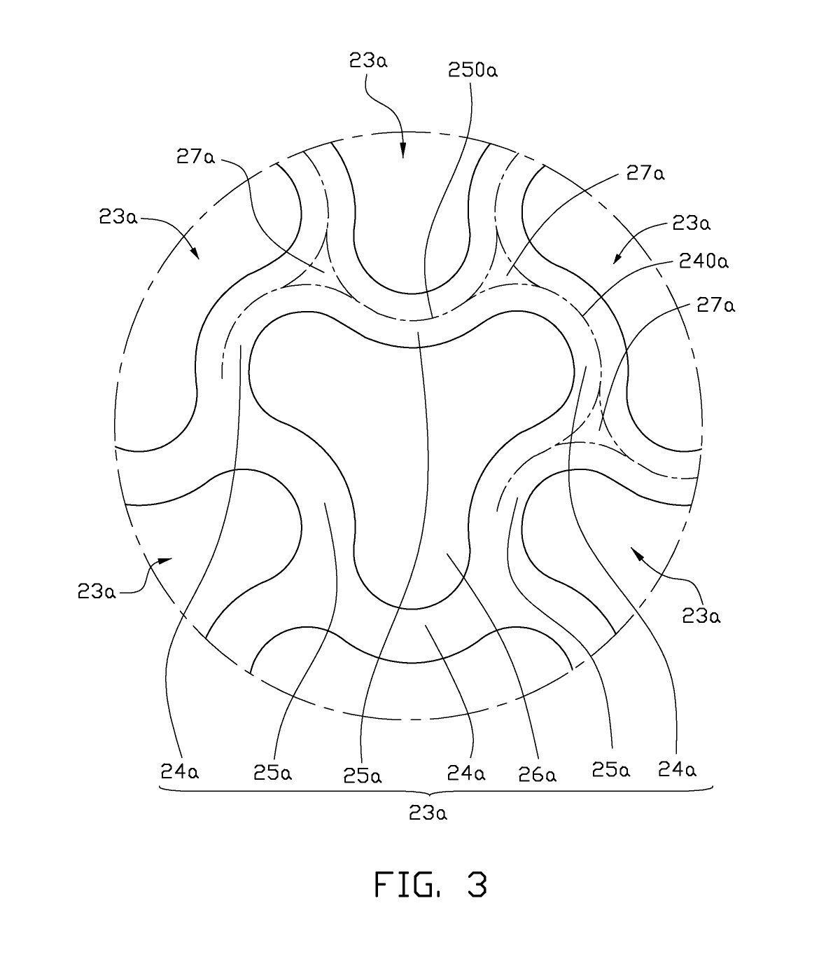

Step S2: punch holes to form a mesh area 22a in the plate 40a, wherein the mesh area 22a defines a plurality of hole units 23a. Referring to FIG. 3, in the first embodiment, each hole unit 23a includes a generally three-pointed-star-shaped hole 26a, three first borders 24a, and three second borders 25a. A diameter of a circumcircle of the hole 26a is 4 mm. The three first borders 24a and the three second borders 25a are alternated to connect end to end, to bound the hole 26a. A center line 240a of each first border 24a is curved. A center line 250a of each second border 25a is curved. In the first embodiment, each center line 240a is a convex arc line, and each center line 250a is a concave arc line, wherein the arc lines are the same shape. Every two adjacent hole units 23a share one first border 24a or one second border 25a. A node 27a is shared by every three adjacent hole units 23a. Any one of the first borders 24a or the second borders 25a is connected between two adjacent nodes 27a.

Step S3: punch a recessed portion 21 on the plate 40a, to extend and/or bend the mesh area 22a to form a side wall 22 of the recessed portion 21. The vented board 40 is done.

After the step S3, some of the first and second borders 24a and 25a of the hole units 23a of the mesh area 22a are extended to be deformed, to make the mesh area 22a form the side wall 22, and an area of the mesh area 22a increases 20% because of being extended while a thickness of the mesh area 22a remains constant. It is noted that the diameter of the circumcircle of each hole 26a is designed to be about 4 mm is to make sure that a maximum width of the opening of each hole 26a will be no more than 5 mm, one thirtieth of the minimum wavelength of the electromagnetic waves generated by the plurality of electronic elements 10, when the 20% area increasing of the mesh area 22 is achieved after punching. Therefore, the electromagnetic waves can be prevented from escaping outside the shell 20 through the holes 26a. In other embodiments, the diameter of the circumcircle of each hole 26a may be adjusted according to a minimum wavelength of the electromagnetic waves generated by the plurality of electronic elements 10 received in the shell 20 and a desire area increasing extent of the mesh area 22 after the step S3.

Accordingly, the area of the mesh area 22a can be extended to increase at least 20%, which compensates for the poor extensibility of the material and thereby solving the rupturing problem when a plate is extended.

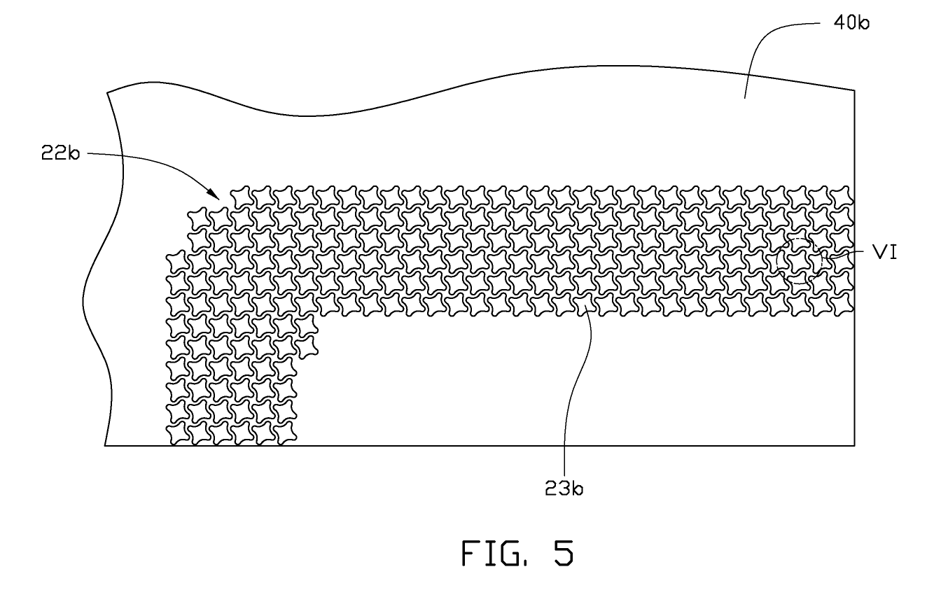

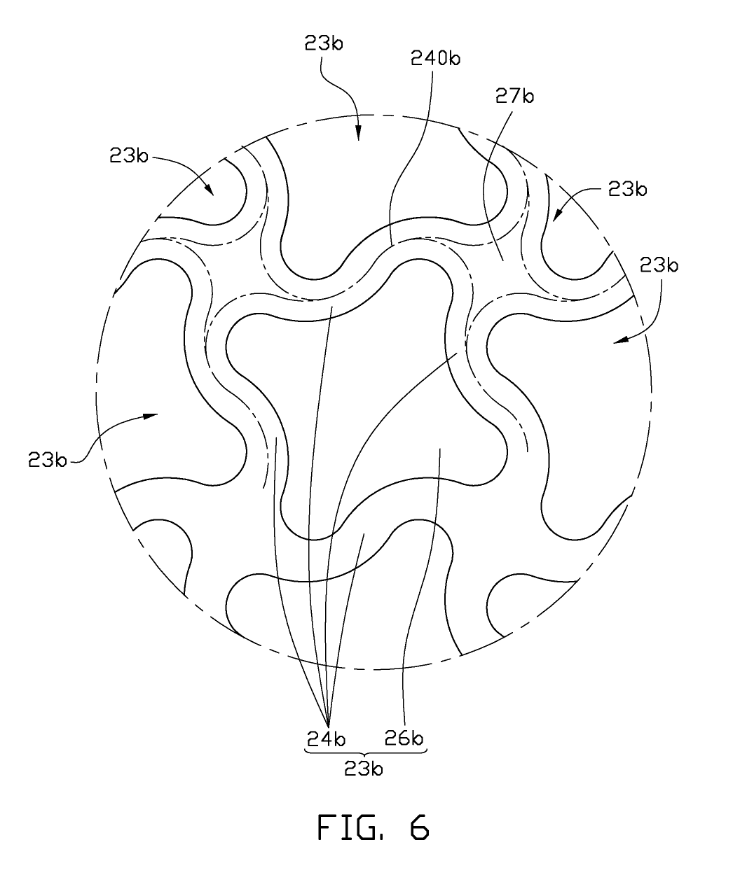

Referring to FIGS. 5 and 6, in a second embodiment, each hole unit 23b of a mesh area 22b in a plate 40b includes a generally four-pointed-star-shaped hole 26b, and four borders 24b. The four borders 24b are connected end to end, to bound the hole 26b. A center line 240b of each border 24b is substantially curved. For example, in the second embodiment, each center line 240b is a wave line. Every two adjacent hole units 23b share one border 24b. A node 27b is shared by every four adjacent hole units 23a. Any one of the borders 24b is connected between two adjacent nodes 27b.

In sum, in the present disclosure, the borders 24a, 25a, and 24b of the mesh areas 22a and 22b are designed to be curve-shaped. When the mesh area 22a or 22b is extended, the borders 24a, 25a, and 24b are extended to tend to be straight, so as to enlarge a size of each hole 26a or 26b. The area of the mesh area 22a or 22b is increased via extending the mesh area 22a or 22b along any direction parallel with the mesh area 22a or 22b, while the thickness of the mesh area 22a or 22b remains constant. Accordingly, it can be seen that the present disclosure substantively employs an innovative way, in which the curve-shaped borders are extended to tend to be straight, to enlarge an area of the material, instead of extending the material to become thin and so as to enlarge the area of the material. Therefore, the rupturing problem caused by thinning the material can be avoided. Furthermore, it can be seen that the method disclosed by the present disclosure fits for multifarious metal materials.

In other embodiments, each hole in the mesh area may be five-pointed-star-shaped, six-pointed-star-shaped, and so on.

In other embodiments, the vented board 40 may be integrally formed with the base 30.

It is to be understood, however, that even though numerous characteristics and advantages of the disclosure have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A metal plate comprising:
a mesh area comprising a plurality of hole units, wherein each hole unit defines a punched hole and comprises a plurality of borders bonding the hole, every two adjacent hole units share one of the plurality of borders, wherein a center line of each border is curved, the mesh area is operable of being extended along any direction parallel with the mesh area to extend some of the plurality of borders, with a thickness of the mesh area substantially remaining constant.

2. The metal plate of claim 1, wherein a center line of each border is arc-shaped.

3. The metal plate of claim 2, wherein the plurality of borders bounding the hole of each hole unit comprises three first borders and three second borders, the three first borders and the three second borders are alternately connected end to end, the center line of each first border is a convex arc line, and the center line of each second border is a concave arc line.

4. The metal plate of claim 2, wherein a node is shared by every three adjacent hole units, any one of the borders is connected between two adjacent nodes.

5. The metal plate of claim 1, wherein the center line of each border is a wave line.

6. The metal plate of claim 5, wherein the number of the plurality of borders bounding the hole of each hole unit is four.

7. The metal plate of claim 5, wherein a node is shared by every four adjacent hole units, any one of the borders is connected between two adjacent nodes.

8. The metal plate of claim 1, wherein a diameter of a circumcircle of the hole of each hole unit is about 4 millimeters.

9. A method for manufacturing a vented board, comprising:
providing a metal plate;
forming a mesh area in the plate, wherein the mesh area comprises a plurality of hole units, each hole unit defines a hole and comprises a plurality of borders bonding the hole, every two adjacent hole units share a corresponding one of the plurality of borders, wherein a center line of each border is a curve line; and
punching a recessed portion on the plate to make at least one part of the mesh area extend to form a side wall of the recessed portion, with a thickness of the mesh area substantially remaining constant.

10. The method of claim 9, wherein in the step of forming a mesh area in the plate, the center line of each border is an arc line.

11. The method of claim 10, wherein in the step of forming a mesh area in the plate, the plurality of borders bounding the hole of each hole unit comprises three first borders and three second borders, the three first borders and the three second borders are alternated to connect end to end, the center line of each first border is a convex arc line, and the center line of each first border is a concave arc line.

12. The method of claim 10, wherein in the step of forming a mesh area in the plate, a plurality of nodes is formed, every three adjacent hole units share one of the plurality of nodes, any one of the plurality of borders is connected between two adjacent nodes.

13. The method of claim 9, wherein in the step of forming a mesh area in the plate, the center line of each border is a wave line.

14. The method of claim 13, wherein in the step of forming a mesh area in the plate, the number of the plurality of borders bounding the hole of each hole unit is four.

15. The method of claim 13, wherein in the step of forming a mesh area in the plate, a plurality of nodes is formed, every four adjacent hole units share one of the plurality of nodes, any one of the plurality of borders is connected between two adjacent nodes.

16. The method of claim 9, wherein in the step of forming a mesh area in the plate, a diameter of a circumcircle of the hole of each hole unit is 4 millimeters.

17. An electronic device, comprising:
a plurality of electronic elements; and
a shell comprising a base for receiving the plurality of electronic elements, and a vented board covering on the base;
wherein a method forming the vented board comprises:
providing a metal plate;
forming a mesh area in the plate, wherein the mesh area comprises a plurality of hole units, each hole unit defines a hole and comprises a plurality of borders bonding the hole, every two adjacent hole units share a corresponding one of the plurality of borders, wherein a center line of each border is a curve line; and
punching a recessed portion on the plate to make at least one part of the mesh area extend to form a side wall of the recessed portion, with a thickness of the mesh area substantially remaining constant.

18. The electronic device of claim 17, wherein the plurality of borders bounding the hole of each hole unit comprises three first borders and three second borders, the three first borders and the three second borders are alternated to connect end to end, wherein before punching the recessed portion, the center line of each first border is a convex arc line, the center line of each first border is a concave arc line.

19. The electronic device of claim 18, wherein the number of the plurality of borders bounding the hole of each hole unit is four, and before punching the recessed portion, the center line of each border is a wave line.

20. The electronic device of claim 18, wherein before punching the recessed portion, a diameter of a circumcircle of the hole of each hole unit is about 4 millimeters.
